(19) United States
(12) Patent Application Publication
(10) Pub. No.: US 2009/0096473 A1
(43) Pub. Date: Apr. 16, 2009

(54) TESTING PROBE AND ELECTRICAL CONNECTION METHOD USING THE SAME

(75) Inventors: Jung-Ju Tsai, Taipei City (TW); Chia-Lung Wu, Taipei City (TW); Ching-Chien Yen, Taipei City (TW); Hsiu-Feng Lee, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: COMPAL ELECTRONICS, INC., Taipei City (TW)

(21) Appl. No.: 12/032,699

(22) Filed: Feb. 18, 2008

(30) Foreign Application Priority Data
Oct. 16, 2007 (TW) 96138664

(51) Int. Cl. G01R 1/067

(52) U.S. Cl. 324/757

(57) ABSTRACT

A testing probe including a shaft body and a plurality of claws is provided. Each cross section of the shaft body has a substantially identical shape and a substantially identical outer diameter. The claws are formed integrally with the shaft body at an end thereof. An orthogonal projection of the claws on any one of the cross sections of the shaft body is within the contour of the cross section. Contacting a solder bump on a test pad of a circuit board with the claws of the testing probe increases the test yield of the circuit board.

### CROSS-REFERENCE TO RELATED APPLICATION

This application claims the priority benefit of Taiwan application serial no. 96138664, filed on Oct. 16, 2007. The entirety of the above-mentioned patent application is hereby incorporated by reference herein and made a part of this specification.

### BACKGROUND OF THE INVENTION

1. Field of the Invention

The present invention generally relates to a testing probe and an electrical connection method using the probe, and in particular, to a testing probe for contacting a test pad of a circuit board and an electrical connection method using the testing probe.

2. Description of Related Art

With the development of technology, electronic products have become indispensable products in the daily life of human beings. Since circuit boards mainly function to carry and connect many electronic components, it is quite important to test circuits of the finished circuit boards to check if the circuits function normally.

In the conventional art, the testing method of the circuit board includes first printing a solder on a plurality of test pads on the circuit board. Then, the solder is reflowed to fix on the test pads to form a plurality of solder bumps. After that, a plurality of pyramidal probes contacts and electrically connects with the solder bumps respectively, so as to test whether the circuit of the circuit board is normal or not.

However, a flux is separated out from the solder after the solder is reflowed and formed on the surface of the solder bump. As for the solder bump formed on the solid test pad, when the tip of the probe contacts the surface of the solder bump, the tip of the probe exerts a pressure on the solder bump, such that the flux is attached or accumulated on the surface of the probe. Therefore, when the probe with the flux accumulated thereon contacts the next solder bump, the flux may prevent the electrical conduction between the probe and the solder bump.

As for the solder bump formed on the via pad (hollow test pad) of the conductive through via, since a portion of the solder bump sinks into the hollow portion of the testing hole, the top of the solder bump is depressed towards the testing hole, such that the contact area between the tip of the probe and the solder bump is reduced. Therefore, the tip of the probe exerts a greater pressure on the solder bump with depressed top, such that the flux on the solder bump is more likely to be accumulated on the tip of the probe.

On the other hand, when the probe is used to contact the solder bump so as to test whether the circuit of the circuit board is normal or not, the tip of the probe may exceed the position tolerance between the probe and the solder bump, and cannot contact the solder bump, thus leading to a test error.

### SUMMARY OF THE INVENTION

The present invention is directed to a testing probe capable of increasing the test yield of the circuit board.

The present invention provides an electrical connection method, for electrically connecting a test equipment to a test pad of a circuit board, so as to increase the test yield of the circuit board.

The present invention provides a testing probe, which includes a shaft body and a plurality of claws. Each cross section of the shaft body has a substantially identical shape and outer diameter. The claws are formed integrally with the shaft body at an end thereof. An orthogonal projection of the claws on any one of the cross sections of the shaft body is within the contour of the cross section.

In an embodiment of the present invention, shapes of the claws are substantially pyramids, and each of the claws includes a tip and at least one crest line.

In an embodiment of the present invention, the tips of the claws are substantially arranged symmetrically with respect to a central line of the shaft body.

In an embodiment of the present invention, the tips of the claws are substantially arranged in an array.

In an embodiment of the present invention, the tips of the claws are substantially located on one plane parallel to any one of the cross sections of the shaft body.

The present invention provides an electrical connection method for electrically connecting a test equipment to a test pad of a circuit board. First, a solder bump is formed on the test pad, and a surface of the solder bump is raised to form a camber relative to a surface of the circuit board. Then, a testing probe electrically connected to a test equipment is used to contact the solder bump. The testing probe has a plurality of claws, and at least one of the claws contact the solder bump.

In an embodiment of the present invention, when the test pad is a via pad of a conductive through via, a hollow of the conductive through via is filled before the solder bump is formed.

In an embodiment of the present invention, shapes of the claws are substantially pyramids, and each of the claw includes a tip and at least one crest line.

In an embodiment of the present invention, the testing probe contacts the solder bump by the tips of the claws.

In an embodiment of the present invention, the testing probe contacts the solder bump by the crest lines of the claws.

In an embodiment of the present invention, the tips of the claws are substantially located on one plane.

In view of the above, the claws of the testing probe are used to contact the solder bump on the test pad of the circuit board, so as to electrically connect the solder bump. Therefore, a large position tolerance is allowed between the testing probe and the solder bump, such that the testing probe may contact the solder bump more easily. Moreover, the testing probe exerts a smaller pressure on the solder bump, such that a flux on the solder bump is not likely attached and accumulated on the testing probe, thus ensuring a sustaining use of the testing probe.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic view illustrating a testing probe used to electrically connect a test pad of a circuit board according to an embodiment of the present connect a test pad of a circuit board according to an embodiment of the present invention.

FIG. 1B is another schematic view of FIG. 1A.

FIG. 2 is a schematic view illustrating a testing probe used to electrically connect a test pad of a circuit board according to another embodiment of the present invention.

FIG. 3A is a schematic view of a structure of a testing probe according to an embodiment of the present invention.

FIG. 3B is a schematic view of a structure of a testing probe according to another embodiment of the present invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

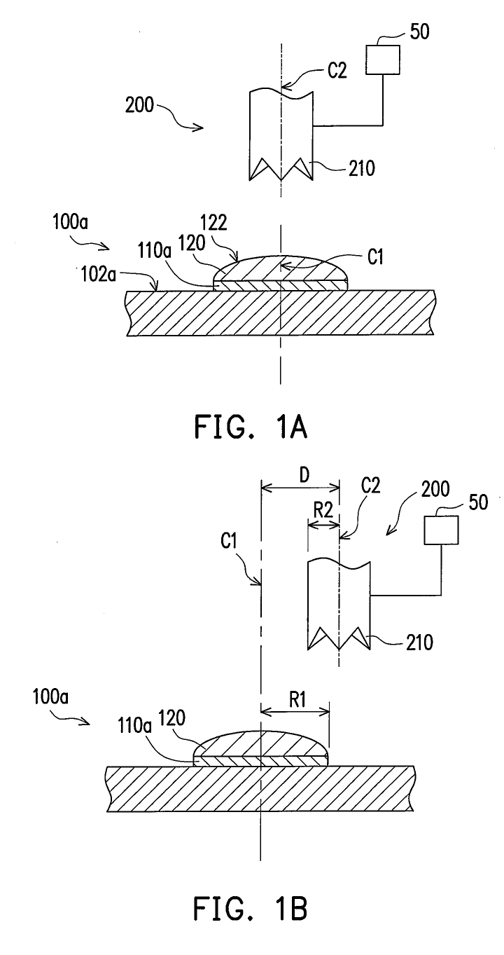

FIG. 1A is a schematic view illustrating a testing probe used to electrically connect a test pad of a circuit board according to an embodiment of the present invention. Referring to FIG. 1A, first, a solder bump 120 is formed on a test pad 110a of a circuit board 100a. A surface 122 of the solder bump 120 is raised to form a camber relative to a surface 102a of the circuit board 100a. In this embodiment, a layer of solder paste is first coated on the test pad 110a, and then reflowed to form the solder bump 120.

After the solder bump 120 is formed, a testing probe 200 having a plurality of claws 210 is used to contact the solder bump 120, so as to electrically connect a test equipment 50 to the test pad 110a of the circuit board 100a. Then, the test equipment 50 determines whether the circuit of the circuit board 100a is normal or not.

In this embodiment, an orthogonal projection of the testing probe 200 on the solder bump 120 is within a contour of the solder bump 120, and a central line C1 of the solder bump 120 may coincide with a central line C2 of the testing probe 200. Therefore, the testing probe 200 may contact the solder bump 120 by the claws 210 simultaneously, so as to test whether the circuit of the circuit board 100a is normal or not. At this time, the testing probe 200 exerts a smaller pressure to the solder bump 120. Therefore, different from the conventional art, if the flux is remained on the solder bump 120, the flux is not likely attached and accumulated on the claws 210, thereby improving the test yield of the circuit board 100a.

FIG. 1B is another schematic view of FIG. 1A. Referring to FIG. 1B, in this embodiment, the central line C1 of the solder bump 120 is deviated from the central line C2 of the testing probe 200 due to the mechanical alignment. Moreover, a distance D between the central line C2 of the testing probe 200 and the central line C1 of the solder bump 120 is greater than a radius R1 of the solder bump 120a, but is smaller than a sum of the radius R1 of the solder bump 120a and a radius R2 of the testing probe 200. Here, the central line C2 of the testing probe 200 is out of the contour of the solder bump 120.

It should be noted that the testing probe 200 may contact the solder bump 120 by at least one of the claws 210, so as to electrically connect the test pad 110a. Therefore, different from the conventional art, when the testing probe 200 having the claws 210 in this embodiment contacts the solder bump 120 on the test pad 110a, a larger position tolerance between the testing probe 200 and the solder bump 120 is allowed, thus a misjudgement rate caused by the testing probe 200 exceeding the position tolerance is reduced, and the test yield of the circuit board 100a is improved.

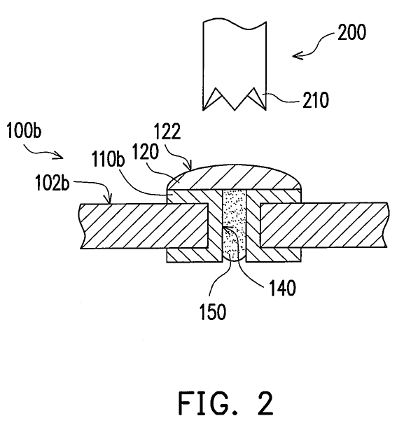

FIG. 2 is a schematic view illustrating a testing probe used to electrically connect a test pad of a circuit board according to another embodiment of the present invention. Referring to FIG. 2, this embodiment is similar to the previous one, except that the structure of the test pad 110b of the circuit board 100b in this embodiment is different from the structure of the test pad 110a of the circuit board 100a in the previous embodiment. In this embodiment, the test pad 110b is a via pad (i.e., a hollow test pad) of a conductive through via 140.

In this embodiment, a filling material 150 is filled in the hollow portion of the conductive through via 140 before the solder bump 120 is formed, such that a depressed top of the solder bump in conventional art is not likely formed. As compared with the conventional art, a surface 122 of the solder bump 120 is easily raised to form a camber relative to a surface 102b of the circuit board 100b, so as to maintain a large contact area between the solder bump 120 and the testing probe 200. Therefore, the testing probe 200 exerts a smaller pressure to the solder bump 120, and thus the flux is not likely attached and accumulated on the claws 210, thereby ensuring a sustaining use of the testing probe 200.

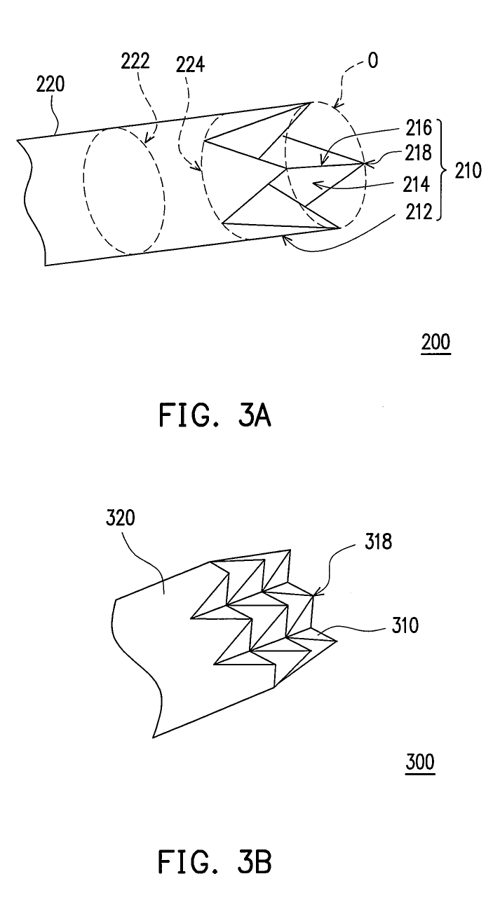

FIG. 3A is a schematic view of a structure of a testing probe according to an embodiment of the present invention. Referring to FIG. 3A, in this embodiment, the testing probe 200 includes four claws 210 and one shaft body 220. Each cross section 222 of the shaft body 220 is round, and the outer diameter of the shaft body 220 is substantially maintained consistent. Furthermore, the claws 210 are formed integrally with the shaft body 220 at an end 224 thereof, and the orthogonal projection of the claws 210 on any one of the cross sections 222 of the shaft body 220 is within the contour of the cross sections 222.

In this embodiment, shapes of the claws 210 are pyramids, and the claws 210 may extend out from an end 224 of the shaft body 220 in a direction perpendicular to the cross sections 222. Moreover, each claw 210 has one cambered surface 212 and two planes 214 adjacent to the cambered surface 212. Furthermore, three crest lines 216 are formed at junctions of the cambered surface 212 and the planes 214, and the crest lines 216 are connected together at a position away from the shaft body 220, so as to form a tip 218.

Moreover, every two of the four claws 210 are symmetrical and facing each other, such that the tips 218 are substantially arranged symmetrically with respect to a central line of the shaft body 220 on a round O. The round O is parallel to the cross section 222, and has a diameter substantially identical with the outer diameter of the shaft body 220, such that the orthogonal projections of the cambered surface 212, the planes 214, the crest lines 216, and the tips 218 on the cross section 222 are within the range of the cross section 224. Besides, in other embodiments (not shown), the diameter of the round O may be smaller than the outer diameter of the shaft body 220.

Then, referring to FIGS. 1B and 3A, when the central line C2 of the testing probe 200 is deviated out of the contour of the solder bump 120 due to the mechanical alignment, the testing probe 200 may also contact the solder bump 120 by at least one of the crest lines 216 and the tips 218 of the claws 210.

FIG. 3B is a schematic view of a structure of a testing probe according to another embodiment of the present invention. Referring to FIG. 3B, in the previous embodiment in FIG. 3A, the tips 218 of the testing probe 200 are also substantially arranged symmetrically with respect to a central line of the shaft body 220 on the round O. However, in the embodiment in FIG. 3B, the tips 318 of the claws 310 at an end of the shaft body 320 of the testing probe 300 are substantially arranged in an array.

In view of the above, in the above embodiments of the present invention, the testing probe has a plurality of claws and may contact the solder bump on the test pad by one of the claws to electrically connect the test pad. Therefore, when the testing probe is used to test the circuit board, a large position tolerance between the testing probe and the solder bump is allowed, such that the testing probe is easier to contact the solder bump, thus improving the test yield of the circuit board.

Moreover, when the testing probe contacts the solder bump by a plurality of claws simultaneously, the testing probe exerts a smaller pressure to the solder bump. Therefore, the flux remained on the solder bump is not likely attached and accumulated on the claws, thus ensuring a sustaining use of the testing probe.

Furthermore, a filling material may be filled in the hollow portion of the conductive through via before the solder bump is formed, such that the solder bump may not sink into the conductive through via. Therefore, the top of the solder bump is easily raised to form a camber relative to the circuit board, so as to maintain a large contact area between the solder bump and the testing probe.

Though the present invention has been disclosed above by the preferred embodiments, they are not intended to limit the present invention. Anybody skilled in the art can make some modifications and variations without departing from the spirit and scope of the present invention. Therefore, the protecting range of the present invention falls in the appended claims and their equivalents.

1. (canceled)

2. (canceled)

3. (canceled)

4. (canceled)

5. (canceled)

6. An electrical connection method, for electrically connecting a test equipment to a test pad of a circuit board, the test pad being a via pad of a conductive through via, the electrical connection method comprising:
filling a hollow portion of the conductive through via with a filling material;
forming a solder bump on the test pad, wherein a surface of the solder bump is raised to form a camber relative to a surface of the circuit board, and a material of the solder bump is different from the filling material; and
contacting the solder bump with a testing probe electrically connected to the test equipment, wherein the testing probe comprises a plurality of claws, and at least one of the claws contacts the solder bump and remains flux free after contacting the solder bump.

7. (canceled)

8. The electrical connection method according to claim 6, wherein shapes of the claws are substantially pyramids, and each of the claws comprises a tip and at least one crest line.

9. The electrical connection method according to claim 8, wherein the testing probe contacts the solder bump by the tips of the claws.

10. The electrical connection method according to claim 8, wherein the testing probe contacts the solder bump by the crest lines of the claws.

11. The electrical connection method according to claim 8, wherein the tips of the claws are substantially located on one plane.
